(19) United States
(12) Patent Application Publication
(10) Pub. No.: US 2013/0032898 A1
(43) Pub. Date: Feb. 7, 2013

(54) METAL-GATE/HIGH-k/GE MOSFET WITH LASER ANNEALING AND FABRICATION METHOD THEREOF

(71) Applicant: ALBERT CHIN, Hsinchu City (TW)

(72) Inventor: ALBERT CHIN, Hsinchu City (TW)

(73) Assignee: NATIONAL CHIAO TUNG UNIVERSITY, Hsinchu City (TW)

(21) Appl. No.: 13/198,874

(22) Filed: Aug. 5, 2011

(51) Int. Cl. H01L 29/78; H01L 21/336

(52) U.S. Cl. 257/410; 438/287; 257/E29.255; 257/E21.409

(57) ABSTRACT

The present invention discloses a metal-gate/high-κ/Ge MOSFET with laser annealing and a fabrication method thereof. The fabrication method comprises the following steps: forming a substrate; implanting a source area and a drain area on the substrate; activating the source area and the drain area by first laser light; depositing gate dielectric material on the substrate; annealing high-κ dielectric material by second laser light; and forming a metal gate on the high-κ dielectric material.

### BACKGROUND OF THE INVENTION

1. Field of the Invention

The exemplary embodiment(s) of the present invention relates to a MOSFET and a fabrication method thereof. More specifically, the exemplary embodiment(s) of the present invention relates to a metal-gate/high-κ/Ge MOSFET with laser annealing and a fabrication method thereof.

2. Description of the Related Art

The MOSFET is biased at V_{g}=V_{d,sat} for higher I_{d} rather than at a low V_{g} with good peak mobility. This is quite challenging because the mobility decreases at higher effective field, due to closer carrier wave-function to high-κ dielectric with stronger interface roughness scaling. The tough challenge is shown in the slow equivalent-oxide thickness (EOT) scaling of high-κ+metal-gate CMOS: from 1.0 nm EOT at 45 nm node to only 0.95 nm EOT at 32 nm node, disclosed by C.-H. Jan, M. Agostinelli, M. Buehler, Z.-P. Chen, S.-J. Choi, G. Curello, H. Deshpande, S. Gannavaram, W. Hafez, U. Jalan, M. Kang, P. Kolar, K. Komeyli, B. Landau, A. Lake, N. Lazo, S.-H. Lee, T. Leo, J. Lin, N. Lindert, S. Ma, L. McGill, C. Meining, A. Paliwal, J. Park, K. Phoa, I. Post, N. Pradhan, M. Prince, A. Rahman, J. Rizk, L. Rockford, G. Sacks, A. Schmitz, H. Tashiro, C. Tsai, P. Vandervoorn, J. Xu, L. Yang, J.-Y. Yeh, J. Yip, K. Zhang, Y. Zhang and P. Bai, “A 32 mm SoC platform technology with 2^{nd} generation high-κ/metal gate transistors optimized for ultra low power, high performance, and high density product applications,” in IEDM Tech. Dig., 2009, pp. 647-650.

To improve the I_{d}, Ge channel is used for MOSFET to provide higher v_{eff} and high-field mobility. The poor high-κ/Ge interface and low doping activation at ion-implanted source-drain are the main issue for Ge MOSFET.

Thus, for the demand, designing a metal-gate/high-κ/Ge MOSFET with laser annealing and a fabrication method thereof to achieve both better interface quality and high-field mobility in metal-gate/high-κ/Ge MOSFETs has become an urgent issue for the application in the market.

### BRIEF SUMMARY

A MOSFET with laser annealing is disclosed. A source area and a drain area are disposed on a substrate respectively and are activated by first laser light. Gate dielectric material is disposed on the substrate and high-κ dielectric material is annealed by second laser light. A metal gate is formed on the high-κ dielectric material.

In this invention, a fabrication method is further provided, comprising the following steps: forming a substrate; implanting a source area and a drain area on the substrate; activating the source area and the drain area by first laser light; depositing gate dielectric material on the substrate; annealing high-κ dielectric material by second laser light; and forming a metal gate on the high-κ dielectric material.

Herein, the substrate comprises germanium (Ge). The high-κ dielectric material is made of one material that is selected from a group consisting of Al₂O₃, HfO₂, ZrO₂, TiO₂, La₂O₃, LaAlO, SrTiO₃ and related metal oxynitride. The metal gate is made of one material that is selected from a group consisting of TaN, TiN, Al, Ni, Ir, Pt. The first laser light and the second laser light have a wavelength at a range of 157 nm˜514.5 nm.

With these and other objects, advantages, and features of the invention that may become hereinafter apparent, the nature of the invention may be more clearly understood by reference to the detailed description of the invention, the embodiments and to the several drawings herein.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 is a schematic view illustrating a first embodiment of a structure of a metal-gate/high-κ/Ge MOSFET with laser annealing according to the present invention;

FIG. 2 is a flow chart of a fabrication method according to this invention;

FIG. 3 shows C-V of TaN/ZrO₂/La₂O₃/SiO₂ on Si n-MOS capacitors by laser annealing and control RTA;

FIG. 4 shows J-V of TaN/ZrO₂/La₂O₃/SiO₂ on Si n-MOS capacitors by laser annealing and control RTA;

FIG. 5 shows C-V of TaN/ZrO₂/La₂O₃/SiO₂ on Ge n-MOS capacitors by laser annealing and control RTA;

FIG. 6 shows J-V of TaN/ZrO₂/La₂O₃/SiO₂ on Ge n-MOS capacitors by laser annealing; FIG. 7 shows measured and quantum-mechanical calculated C-V of Ge n-MOS capacitors by laser annealing, with small hysteresis;

FIG. 8 shows gate leakage current vs. EOT of TaN/ZrO₂/La₂O₃/SiO₂/Ge devices by laser annealing;

FIG. 9 shows the n⁺/p junction characteristics of P⁺-implanted Ge by laser annealing and control RTA;

FIG. 10 shows Rₛ of P⁺-implanted Ge by laser annealing and control RTA;

FIG. 11 shows SIMS of TaN/ZrO₂/La₂O₃/SiO₂/Ge by laser annealing;

FIG. 12 shows SIMS of TaN/ZrO₂/La₂O₃/SiO₂/Ge by laser annealing or RTA; smaller diffusion tails of La and Zr are found using laser annealing than RTA;

FIG. 13 shows I_{d}-V_{d} of TaN/ZrO₂/La₂O₃/SiO₂/Ge n-MOSFETs by control RTA;

FIG. 14 shows I_{d}-V_{g} of TaN/ZrO₂/La₂O₃/SiO₂/Ge n-MOSFETs by control RTA;

FIG. 15 shows I_{d}-V_{d} of TaN/ZrO₂/La₂O₃/SiO₂/Ge n-MOSFETs by laser annealing;

FIG. 16 shows I_{d}-V_{g} of TaN/ZrO₂/La₂O₃/SiO₂/Ge n-MOSFETs by laser annealing;

FIG. 17 shows mobility of various Ge n-MOSFETs; the laser annealing gives the highest Qᵢₙᵥ and still good high-field mobility at the lowest 0.95 nm EOT; and

FIG. 18 shows Vₜ shift of n-MOSFETs by laser annealing or control RTA stressed at 85° C. for 1 hr.

### DETAILED DESCRIPTION

Exemplary embodiments of the present invention are described herein in the context of a metal-gate/high-κ/Ge MOSFET with laser annealing and a fabrication method thereof

Those of ordinary skilled in the art will realize that the following detailed description of the exemplary embodiment(s) is illustrative only and is not intended to be in any way limiting. Other embodiments will readily suggest themselves to such skilled persons having the benefit of this disclosure. Reference will now be made in detail to implementations of the exemplary embodiment(s) as illustrated in the accompanying drawings. The same reference indicators will be used throughout the drawings and the following detailed description to refer to the same or like parts.

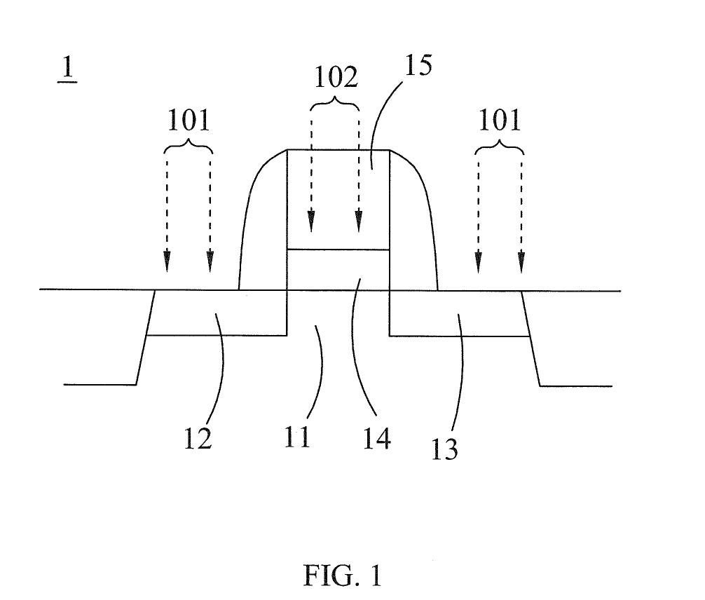

Please refer to FIG. 1 as a schematic view illustrating a first embodiment of a structure of a metal-gate/high-κ/Gc MOSFET with laser annealing according to the present invention. As shown in the figure, the metal-gate/high-κ/Ge MOSFET 1 with laser annealing comprises a germanium (Ge) substrate 11. Also, a source area 12 and a drain area 13 are disposed on the substrate 11 respectively and are activated by the first laser light 101. Gate dielectric material is disposed on the substrate 11 and the high-κ dielectric material 14 is annealed by the second laser light 102. A metal gate 15 is formed on the high-κ dielectric material 14.

In addition, the high-κ dielectric material is made of one material that is selected from a group consisting of Al₂O₃, HfO₂, ZrO₂, TiO₂, La₂O₃, LaAlO, SrTiO₃ and related metal oxynitride. The metal gate is made of one material that is selected from a group consisting of TaN, TiN, Al, Ni, Ir, Pt. The first laser light and the second laser light have a wavelength at a range of 157 nm˜514.5 nm.

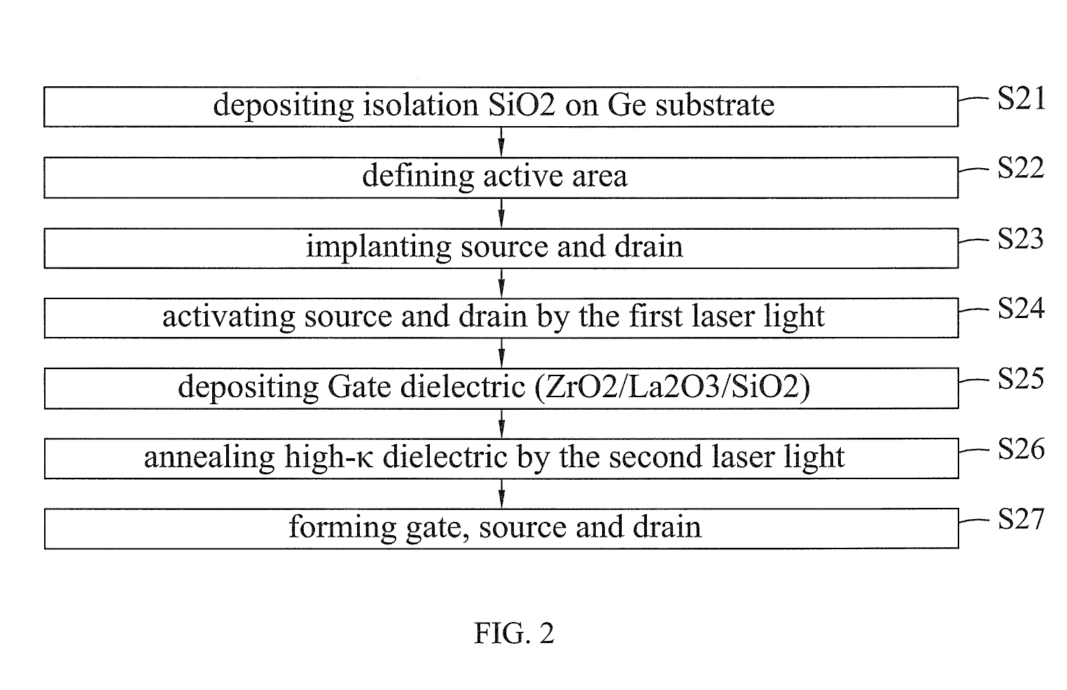

Please refer to FIG. 2 as a flow chart of a fabrication method according to this invention. As shown in the chart, the fabrication method according to this invention is applied to the metal-gate/high-κ/Ge MOSFET with laser annealing. The fabrication method comprises the following steps:

(S21) depositing isolation SiO₂ on Ge substrate;

(S22) defining active area;

(S23) implanting source and drain;

(S24) activating source and drain by the first laser light;

(S25) depositing Gate dielectric (ZrO₂/La₂O₃/SiO₂);

(S26) annealing high-κ dielectric by the second laser light; and

(S27) forming gate, source and drain.

That is, Ge n-MOSFETs were made on standard 2-in p-type Ge wafers for VLSI backend integration. The Ge n-MOSFETs were made by P+ implantation at 35 keV and 5×10¹⁵ cm⁻² to source-drain and 1^{st} KrF laser (248 nm, ˜30 ns pulse). Then 0.8 nm SiO₂, 1 nm La₂O₃ and 3 nm ZrO₂ were deposited and followed by O₂ PDA. The ultra-thin La₂O₃ is used to reach negative flat-band voltage (V_{fb}) and/or threshold voltage (Vt). The ZrO₂ has been used for DRAM manufacture due to its higher κ value. The 2^{nd} laser was applied to increase the Cᵢₙᵥ. The devices were made by forming TaN gate and Al source-drain metal contacts.

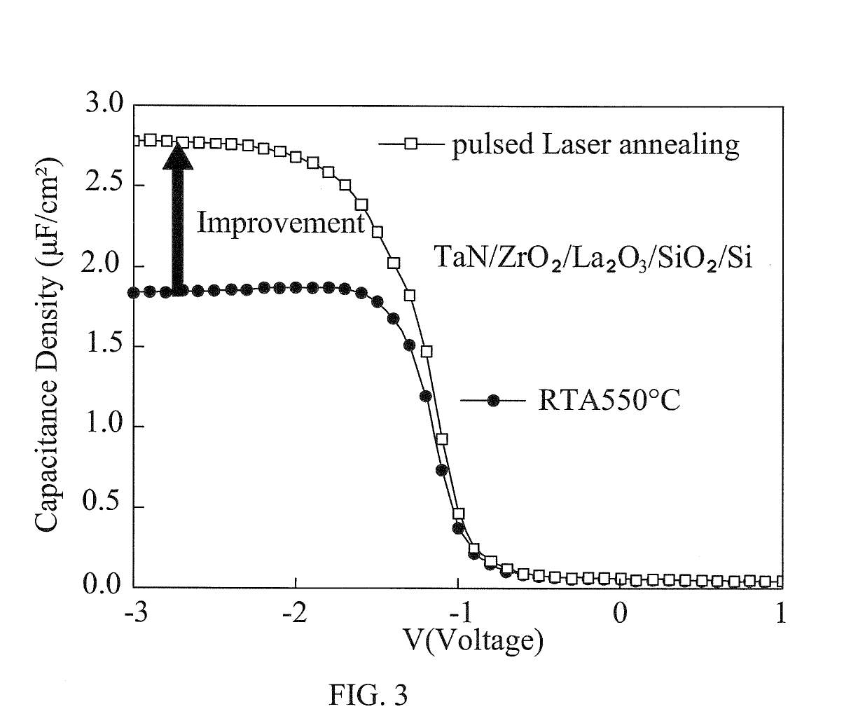

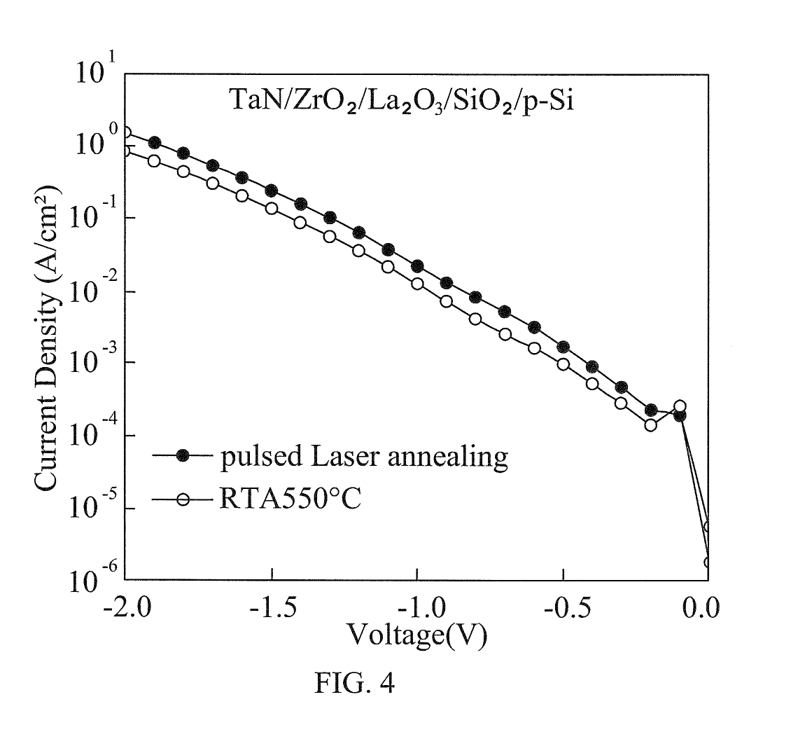

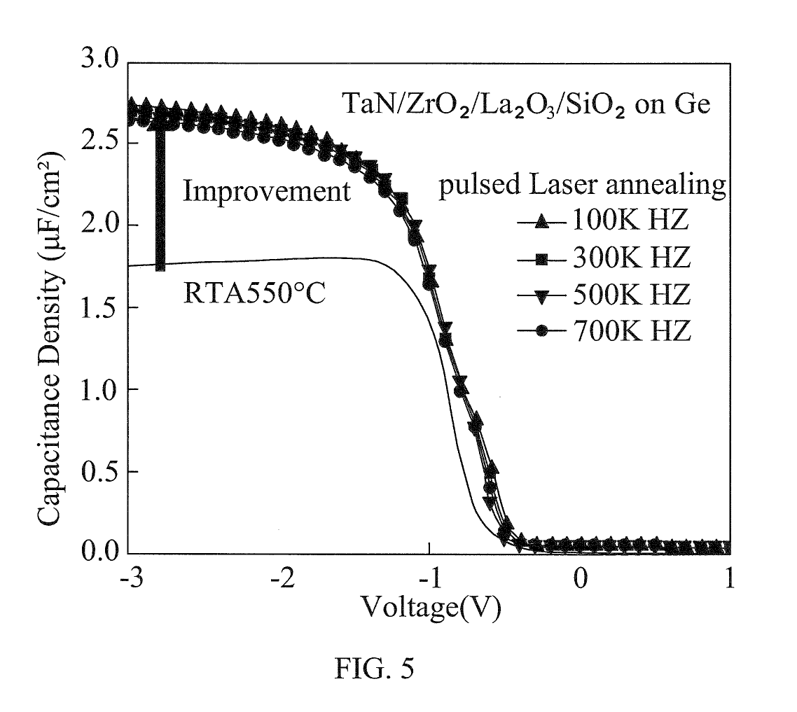

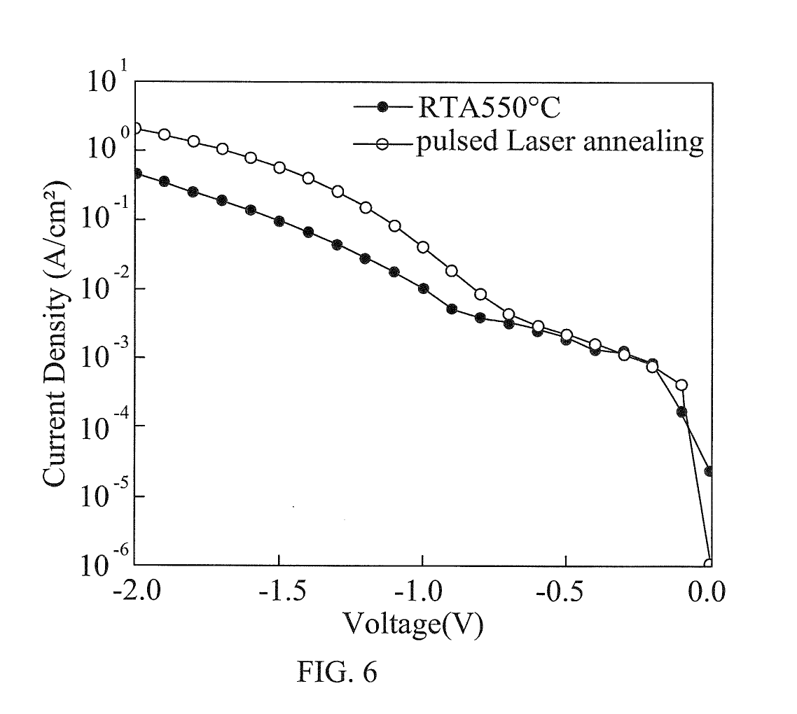

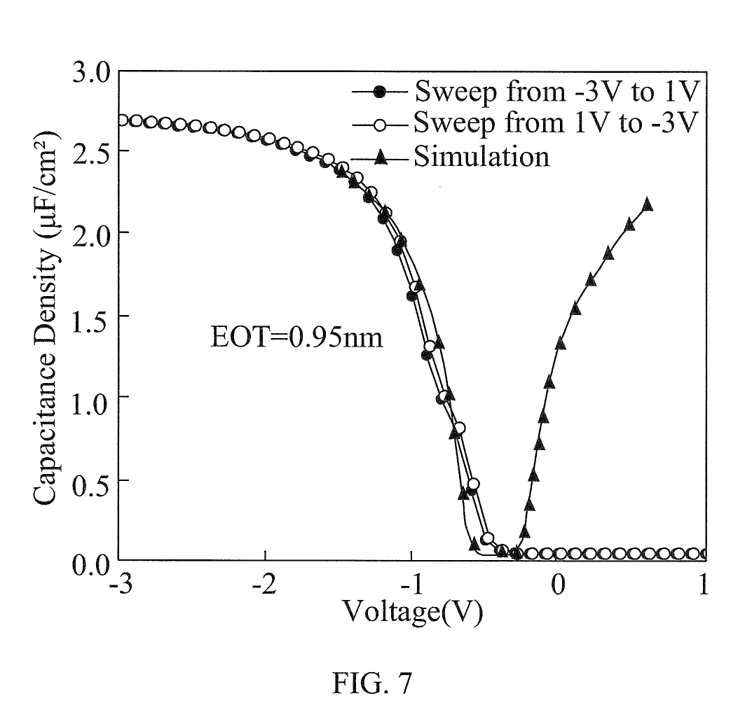

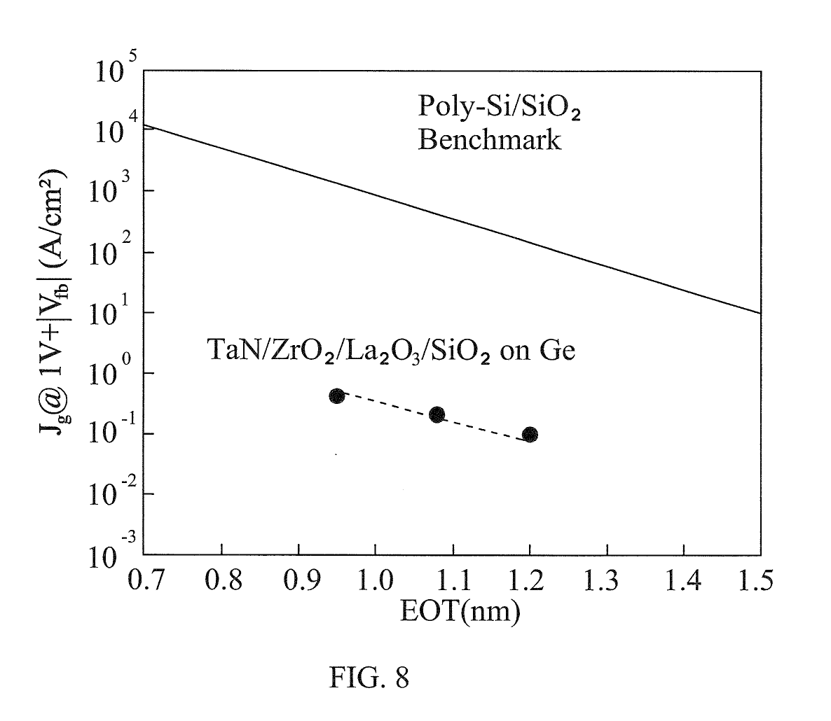

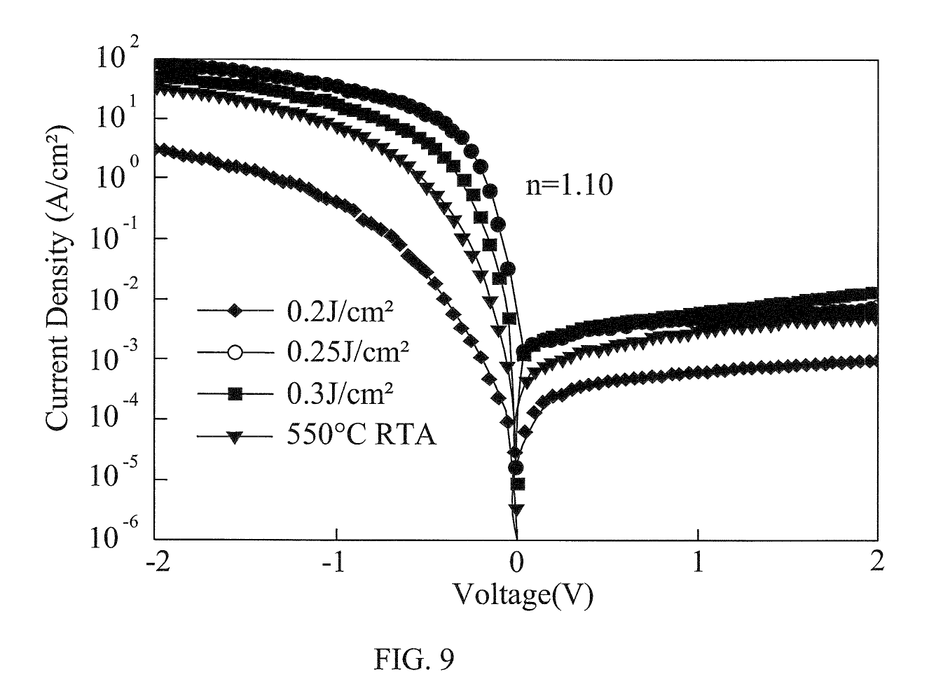

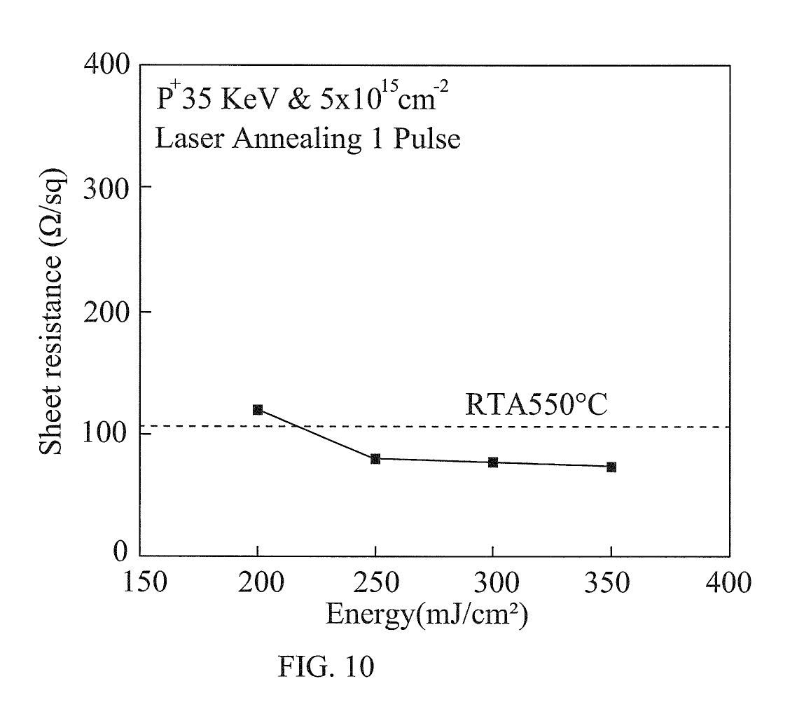

Next, laser annealing on gate stack and source-drain is described. FIGS. 3-6 show the C-V and J-V characteristics of TaN/ZrO₂/La₂O₃/SiO₂ gate stack on control Si and Ge. The laser annealing largely increases the gate capacitance from 1.75 to 2.75 μF/cm² by 57% and overall κ from 9.3 to 14.6, with only small V_{fb} shift and slight increasing gate current (J_{g}). Besides, negligible frequency dispersion is reached with increasing frequency. These results suggest the good oxide/Ge quality after laser annealing. The good gate dielectric quality is further supported by the small C-V hysteresis shown in FIG. 7. An EOT of 0.95 nm is obtained from quantum-mechanical C-V calculation with Ge parameters, which is one of the lowest EOT of Ge n-MOS. FIG. 8 shows the J_{g}-EOT plot at 1 V above More than 3 orders of magnitude lower gate leakage is obtained at 0.95 nm EOT. The laser annealing also improves sheet resistance (Rₛ), n-factor and forward current of ion-implanted n⁺/p Ge junction shown in FIGS. 9-10, while still keeping a low reverse leakage. The Rₛ decreases with increasing laser energy to 0.25 J/cm² and lower than the previous 0.36 J/cm² for Si device, disclosed by C. C. Liao, A. Chin, N. C. Su, M.-F. Li, and S. J. Wang, “Low Vt gate-first Al/TaN/[Ir3Si—HfSi2-x]/HfLaON CMOS using simple laser annealing/reflection,” in Symp. on VLSI Tech. Dig., 2008, pp. 190-191., which is due to the lower melting temperature of Ge than Si. A low Rₛ of ˜73 Ω/sq was obtained by laser annealing and lower than the 106 Ω/sq Rₛ by RTA. Small n-factor of 1.10 is measured in P⁺-implanted n⁺/p junction using laser annealing and also better than control RTA. The shallower junction of ion-implanted Ge is another advantage for MOSFET scaling compared with Si.

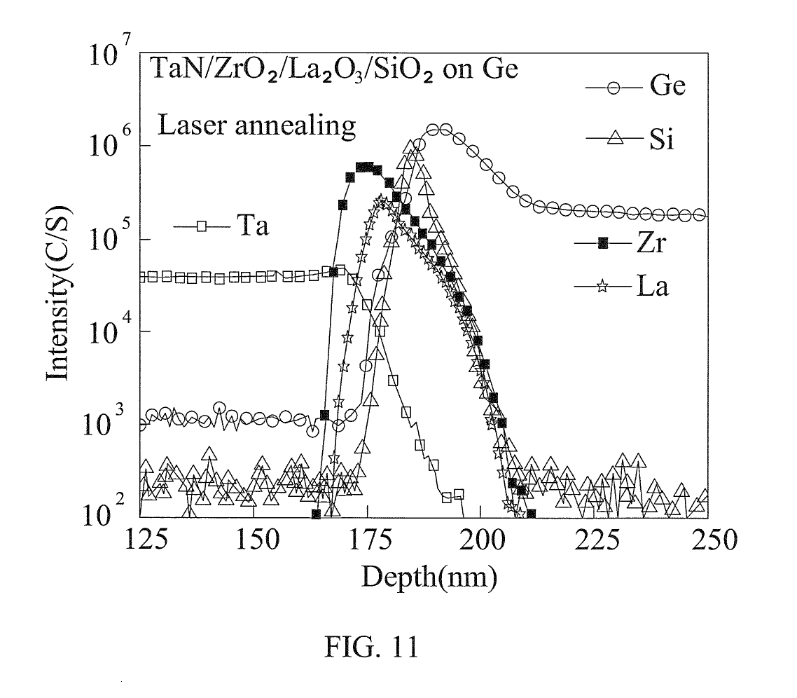

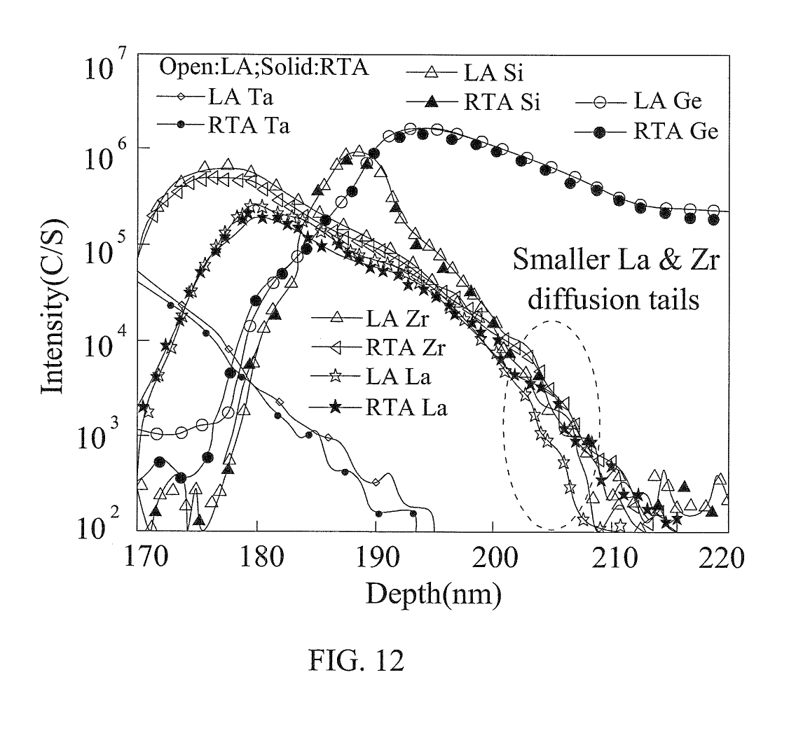

Good oxide/Ge interface was also verified by SIMS shown in FIGS. 11-12, where small Ge out-diffusion and high-κ diffusion through SiO₂ were obtained and slightly better than control RTA. Therefore, the smaller EOT is due to laser annealing-induced higher κ, rather than the high-κ diffusion through SiO₂. These results are important to achieve good oxide/Ge interface and high-field mobility.

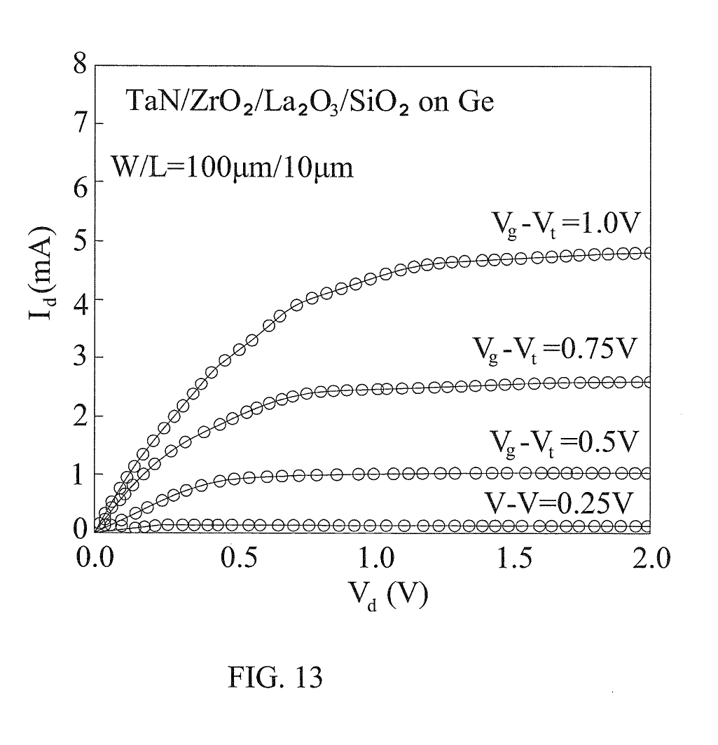

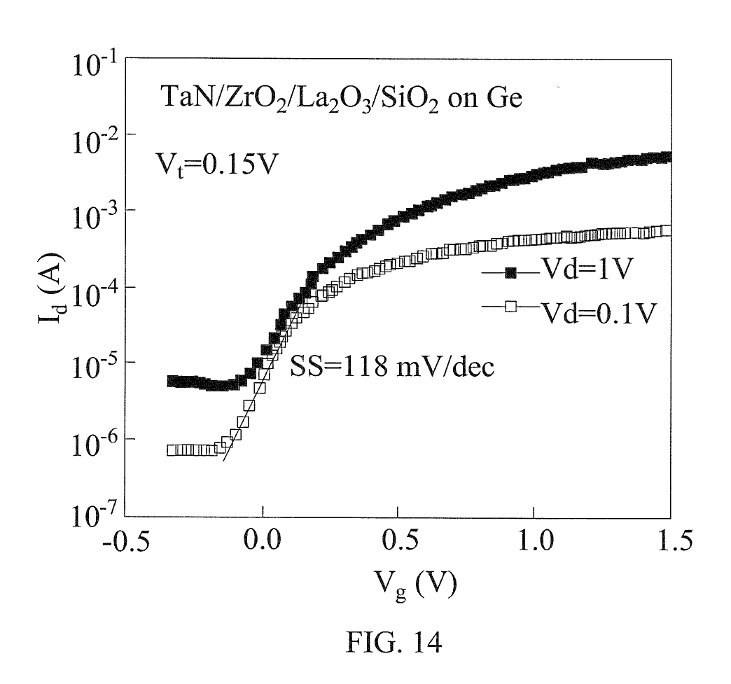

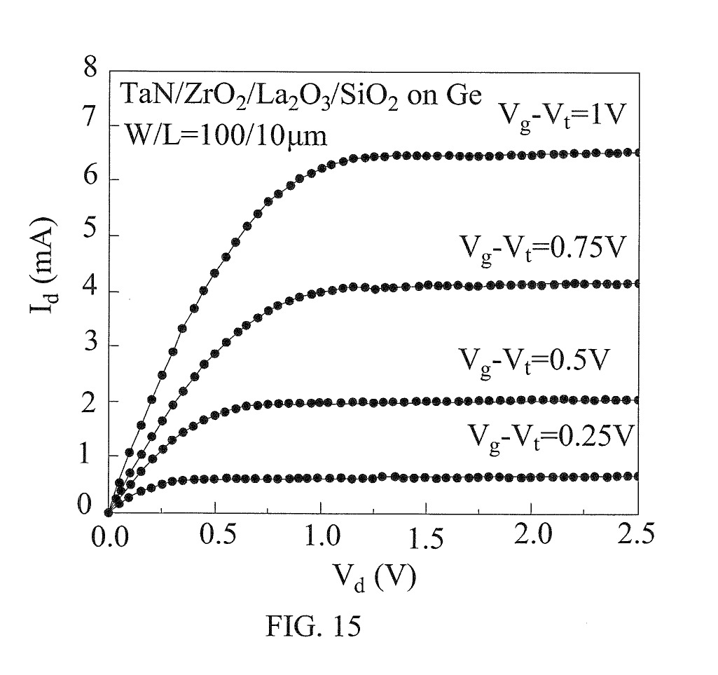

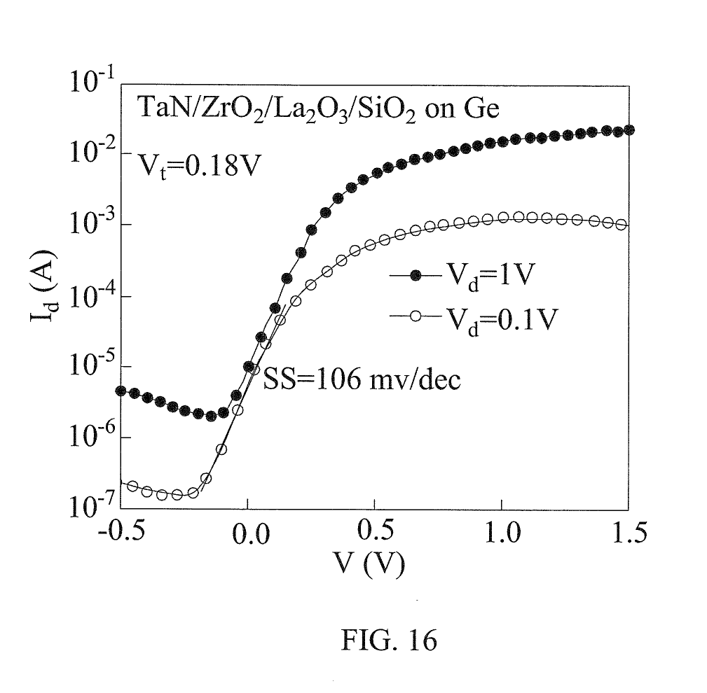

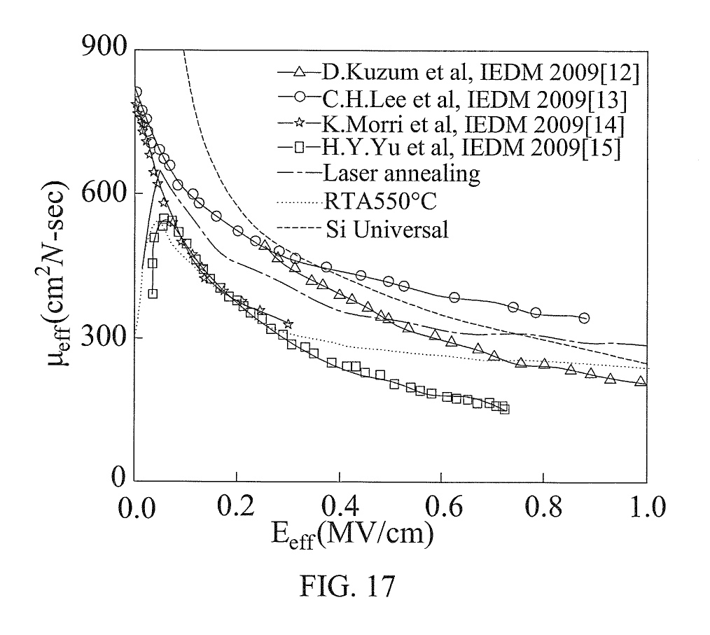

Soon, transistor characteristics by laser annealing are described. The I_{d}-V_{d} and I_{d}-V_{g} data of metal-gate/high-κ/Ge n-MOSFETs are shown in FIGS. 13-16. The device using laser annealing has higher I_{d}, one order of magnitude better I_{ON}/I_{OFF} and smaller 106 mV/dec sub-threshold slope than these of control RTA. The small sub-threshold slope is due to the higher gate capacitance, disclosed by M. F. Chang, P. T. Lee, S. P. McAlister, and Albert Chin, “Low subthreshold swing HfLaO/pentacene organic thin-film transistors,” IEEE Electron Devices Lett., vol. 29, pp. 215-217, March 2008, and relatively good interface. FIG. 17 shows the mobility of this work and other reported data. Good 285 cm²/Vs high-field mobility at 1 MV/cm and 645 cm²/Vs peak mobility are obtained using laser annealing at the small 0.95 nm EOT. It is important to notice that the high-field mobility at 1 MV/cm is 15% higher than the SiO₂/Si universal mobility, disclosed by S. Datta, G. Dewey, M. Doczy, B.S. Doyle, B. Jin, J. Kavalieros, R. Kotlyar, M. Metz, N. Zelick and R. Chau “High mobility Si/SiGe strained channel MOS transistors with HfO2/TiN gate stack,” in IEDM Tech. Dig., 2003, pp. 653-656.

Thus, the higher I_{d} is due to combined effects of smaller EOT, higher mobility and lower Rₒₙ by laser annealing. The higher mobility using laser annealing also indicates the smaller EOT due to laser annealing-induced higher κ, rather than high-κ diffusion to interface with degraded mobility. This is one of the best reported high-field mobility at 1 MV/cm and EOT<1 nm for Ge n-MOSFETs. Such good data at 0.95 nm EOT is comparable with the best Ge n-MOSFET by high pressure oxidation at much larger EOT, disclosed by C. H. Lee, T. Nishimura, N. Saido, K. Nagashio, K. Kita and A. Toriumi, “Record-high electron mobility in Ge n-MOSFETs exceeding Si universality,” IEDM Tech. Dig., 2009, pp. 457-460.

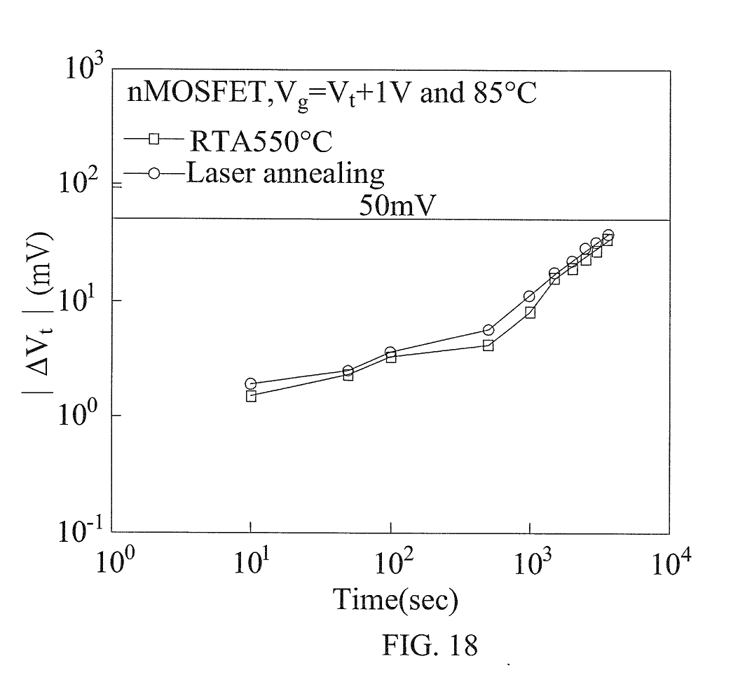

This good high-field mobility is due to the fast 30-ns time and low energy laser annealing with small diffusion length (\sqrt{Dt}) and low interface reaction (e^{-Ea/kT}), disclosed by C. F. Cheng, C. H. Wu, N. C. Su, S. J. Wang, S. P. McAlister and Albert Chin, “Very low Vt [Ir-Hf]/HfLaO CMOS using novel self-aligned low temperature shallow junctions,” in IEDM Tech. Dig., 2007, pp. 333-336, which is supported by the smooth interface observed from TEM shown in FIG. 11. The high performance Ge n-MOSFETs by laser annealing has good reliability from the small 37 mV ΔVt after 85° C. BTI stress for 1 hr (FIG. 18).

To sum up, high performance metal-gate/high-κ/Ge n-MOSFETs are reached with low 73 Ω/sq sheet resistance (Rₛ), 1.10 ideality factor, 0.95 nm EOT, small 106 mV/dec sub-threshold slope, good 285 cm²/Vs high-field (1 MV/cm) mobility and low 37 mV ΔVt PBTI (85° C., 1 hr). This is achieved by using 30-ns laser annealing that leads to 57% higher gate capacitance, better n⁺/p junction and 10× better I_{ON}/I_{OFF}.

While particular embodiments of the present invention have been shown and described, it will be obvious to those skilled in the art that, based upon the teachings herein, changes and modifications may be made without departing from this invention and its broader aspects. Therefore, the appended claims are intended to encompass within their scope of all such changes and modifications as are within the true spirit and scope of the exemplary embodiment(s) of the present invention.

1. A MOSFET with laser annealing comprising:
a substrate;
a source area and a drain area being disposed on the substrate respectively and being activated by first laser light;
gate dielectric material being disposed on the substrate and high-κ dielectric material being annealed by second laser light; and
a metal gate being formed on the high-κ dielectric material after the high-κ dielectric material is annealed by the second laser light.

2. The MOSFET with laser annealing as claimed in claim 1, wherein the substrate comprises germanium (Ge).

3. The MOSFET with laser annealing as claimed in claim 1, wherein the high-κ dielectric material is made of one material that is selected from a group consisting of Al₂O₃, HfO₂, ZrO₂, TiO₂, La₂O₃, LaAlO, SrTiO₃ and related metal oxynitride.

4. The MOSFET with laser annealing as claimed in claim 1, wherein the metal gate is made of one material that is selected from a group consisting of TaN, TiN, Al, Ni, Ir, Pt.

5. The MOSFET with laser annealing as claimed in claim 1, wherein the first laser light and the second laser light have a wavelength absorbable by the substrate.

6. A fabrication method, comprising the following steps of:
forming a substrate;
implanting a source area and a drain area on the substrate;
activating the source area and the drain area by first laser light;
depositing gate dielectric material on the substrate;
annealing high-κ dielectric material by second laser light; and
after the annealing step, forming a metal gate on the high-κ dielectric material.

7. The fabrication method as claimed in claim 6, wherein the substrate comprises germanium (Ge).

8. The fabrication method as claimed in claim 6, wherein the high-κ dielectric material is made of one material that is selected from a group consisting of Al₂O₃, HfO₂, ZrO₂, TiO₂, La₂O₃, LaAlO, SrTiO₃ and related metal oxynitride.

9. The fabrication method as claimed in claim 6, wherein the metal gate is made of one material that is selected from a group consisting of TaN, TiN, Al, Ni, Ir, Pt.

10. The fabrication method as claimed in claim 6, wherein the first laser light and the second laser light have a wavelength absorbable by the substrate.
